(19) United States
(12) Patent Application Publication
(10) Pub. No.: US 2016/0281210 A1
(43) Pub. Date: Sep. 29, 2016

(54) Ophthalmic Lens Holder For Physical Vapor Deposition

(71) Applicant: Vision Ease, LP, Ramsey, MN (US)

(72) Inventors: Michael S. Boulineau, Forest Lake, MN (US); Sandy Goebel, Stacey, MN (US); Glenn M. Campbell, Clearlake, MN (US); Kyle Eggart, Andover, MN (US); John Thomas Moxon, Rogers, MN (US); Michael L. Marshall, Andover, MN (US)

(73) Assignee: Vision Ease, LP, Ramsey, MN (US)

(21) Appl. No.: 15/081,475

(22) Filed: Mar. 25, 2016

Related U.S. Application Data
(60) Provisional application No. 62/138,921, filed on Mar. 26, 2015.

(51) Int. Cl. C23C 14/22; G02B 1/10

(52) U.S. Cl. CPC C23C 14/22; G02B 1/10

(57) ABSTRACT

A system and method for coating an optical lens by, for example vapor deposition, that employs a housing or drum having a plurality of apertures that each receives a lens holder assembly. The lens holding assembly configured to hold a standard, uncut optical lenses or lens blanks or, alternatively, to hold cut, non-standard shaped and sized optical lenses.

### RELATED APPLICATIONS

This application claims benefit of and priority to U.S. Provisional Application Ser. No. 62/138,921 filed Mar. 26, 2015 entitled Ophthalmic Lens Holder for Physical Vapor Deposition, which is hereby incorporated herein by reference in its entirety.

### FIELD OF THE INVENTION

The present invention relates to the coating of optical lenses and, more particularly, to systems and methods for holding optical lenses during a lens coating process.

### BACKGROUND OF THE INVENTION

Anti-reflective coatings reduce reflections off the front and back surfaces of ophthalmic lenses and therefore are desirable for creating eyeglasses with improved light transmission, visibility, and aesthetics. Typically, these anti-reflective coatings must be applied as a series of layers having a precise and relatively thin thickness. In this respect, physical vapor deposition machines, such as sputtering coaters, are often used for the coating application process.

FIG. 1 is a plan view of a horizontally rotating drum 10 for holding a lens 22 for coating a surface 22A of the lens 22 in a vertical orientation within an interior of a sputtering box or chamber. The drum 10 includes a plurality of sides 6 that are separated from each other by divider walls 4. As shown in FIG. 2, each side 6 has a mounting fixture 8 onto which an item, for example the optical lens 22, can be mounted for coating.

In operation, an ophthalmic lens 22 is mounted to the fixture 8 via a double-sided adhesive pad or tape 20. One drawback to this mounting style is that a backside 22B of the lens 22 must be completely covered with an adhesive tape 20 or similar covering to prevent portions of the backside 22B of the lens 22 from also being coated. Since this back covering must precisely and completely cover the backside 22B surface of the lens 22, the tape 20 can be time consuming to apply. Additionally, the adhesive nature of the double-sided adhesive pad 20 often prevents the tape 20 from being reused for the coating of more than one lens 22.

What is needed in the art is a drum and lens holder system that is more robust, reusable, and allows for a more efficient holding and exchange of lenses of varying shapes and sizes.

### OBJECTS AND SUMMARY OF THE INVENTION

The present invention provides a drum and lens holder system that is more robust, reusable, and allows for a more efficient holding and exchange of lenses of varying shapes and sizes. This is achieved, in part, by providing a system for coating optical lenses comprising: a housing having at least two sides through which an aperture is formed; and a lens holder having a lens aperture that accepts an optical lens, an exterior shape and size that is complementary and is accepted within the aperture of the housing, and a magnetic back surface.

This is also achieved, in part, by providing a system for coating optical lenses comprising: a housing having a plurality of sides with first apertures; and an annular lens holder accepted within one of the first apertures, the lens holder having a second aperture that accepts an optical lens; and a securing element that maintains the lens holder within the first aperture, the securing element incorporating a magnet associated with each of the first apertures and a magnetic back surface of the lens holder.

This is further achieved, in part, by providing a method for holding an optical lens during coating comprising: inserting an optical lens within a lens holding assembly; securing the lens holding assembly within an aperture of a housing by forming a magnetic attraction between a substantially entire back surface of the lens holder and a magnet of the housing; preventing a backside of the optical lens from being coated; loading the housing into a coating device; and coating at least a portion of the optical lens while rotating the housing within the coating device.

### BRIEF DESCRIPTION OF THE DRAWINGS

These and other aspects, features and advantages of which embodiments of the invention are capable of will be apparent and elucidated from the following description of embodiments of the present invention, reference being made to the accompanying drawings, in which

FIG. 1 is a plan view of a drum for a vapor deposition coater system according to one embodiment of the present invention;

FIG. 2 is an elevation view of a drum for a vapor deposition coater system according to one embodiment of the present invention;

FIG. 3 is a plan view of a drum for a vapor deposition coater system according to one embodiment of the present invention;

FIG. 4 is an elevation view of a drum for a vapor deposition coater system according to one embodiment of the present invention;

FIG. 5 is a plan view of a lens holder fixture according to one embodiment of the present invention;

FIG. 6 is a front plan view of a lens holder fixture according to one embodiment of the present invention;

FIG. 7 is a front plan view of a lens holder fixture according to one embodiment of the present invention;

FIG. 8 is a back plan view of a lens holder fixture according to one embodiment of the present invention;

FIG. 9 is an elevation view of a drum for a vapor deposition coater system according to one embodiment of the present invention;

FIG. 10 is an elevation view of a drum for a vapor deposition coater system according to one embodiment of the present invention;

FIG. 11 is a perspective view of a drum for a vapor deposition coater system according to one embodiment of the present invention;

FIG. 12A is a back plan view of a lens holder assembly according to one embodiment of the present invention;

FIG. 12B is a back plan view of a lens holder assembly according to one embodiment of the present invention;

FIG. 13A is a cross-sectional view of a lens holder assembly according to one embodiment of the present invention;

FIG. 13B is a cross-sectional view of a lens holder assembly according to one embodiment of the present invention;

FIG. 13C is a cross-sectional view of a lens holder assembly according to one embodiment of the present invention;

FIG. 14 is a plan view of a lens holder assembly according to one embodiment of the present invention;

FIG. 15 is a perspective view of a lens holder assembly according to one embodiment of the present invention; and

FIG. 16 is a perspective view of a lens holder assembly according to one embodiment of the present invention.

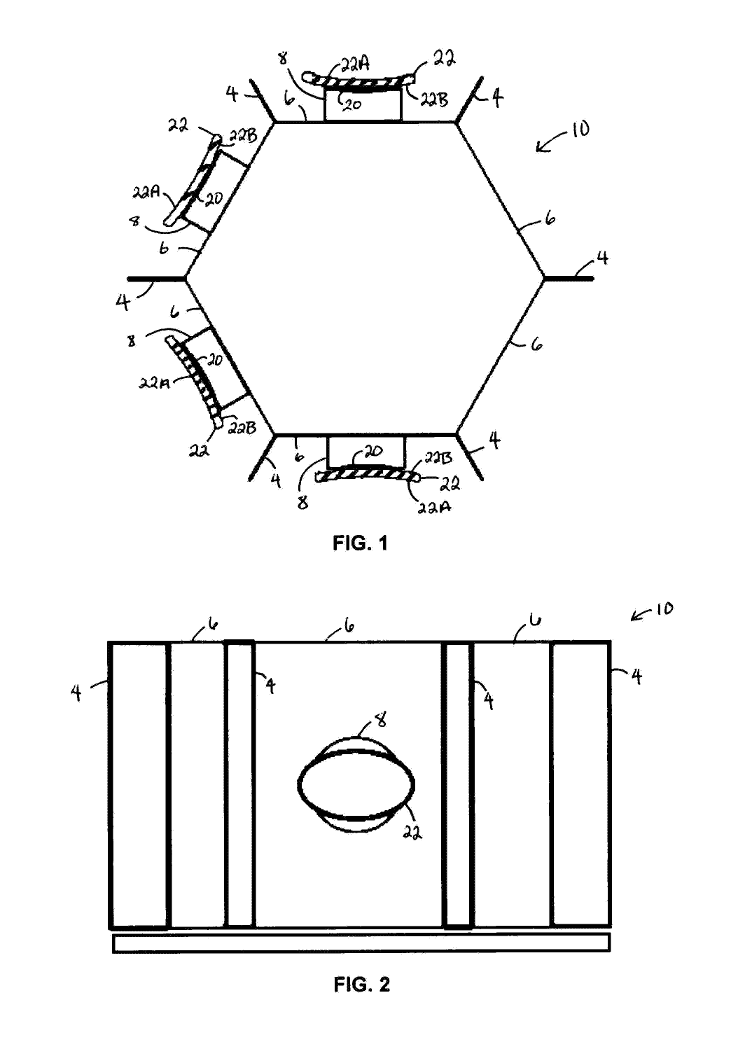

### DESCRIPTION OF EMBODIMENTS

Specific embodiments of the invention will now be described with reference to the accompanying drawings. This invention may, however, be embodied in many different forms and should not be construed as limited to the embodiments set forth herein; rather, these embodiments are provided so that this disclosure will be thorough and complete, and will fully convey the scope of the invention to those skilled in the art. The terminology used in the detailed description of the embodiments illustrated in the accompanying drawings is not intended to be limiting of the invention. In the drawings, like numbers refer to like elements.

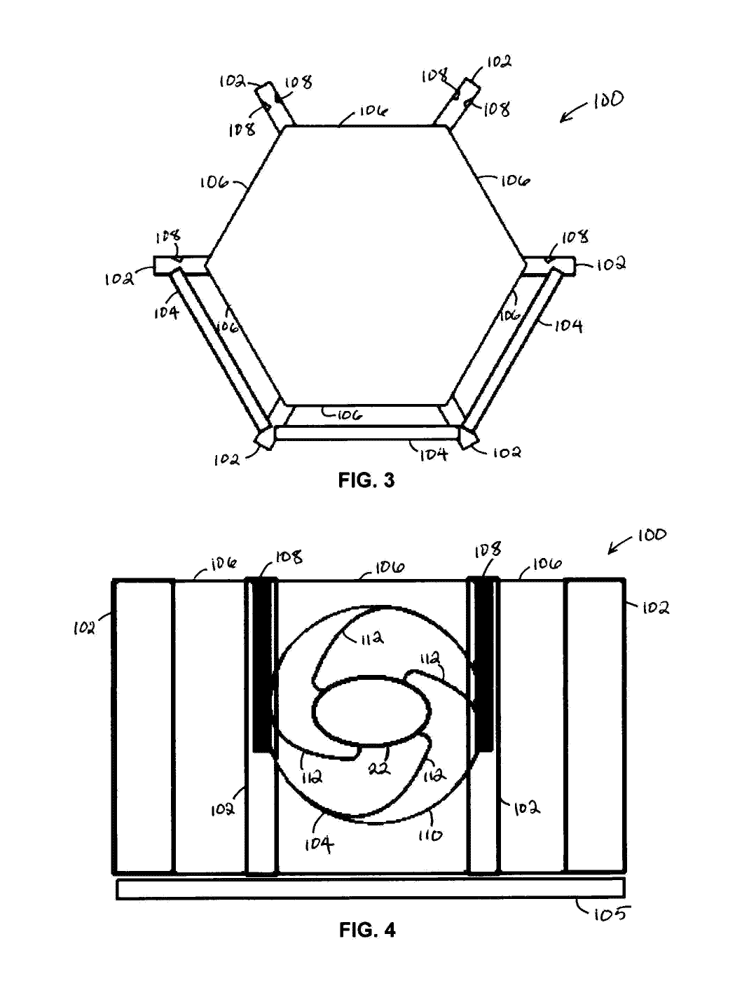

With reference to FIGS. 3 and 4, one embodiment of the present invention employs a housing or drum 100 having a plurality of divider walls 102 that extend from the intersections of a plurality of drum sides 106. For example, the drum 100 may employ six sides 106, as shown in FIG. 3, or as few as two drum sides 106. The lens retaining system includes a spring clip ring 104 within which the lens 22 is retained or secured. The spring clip ring 104 is, in turn, secured to the drum 100 by guides 108 that are formed vertically within the divider walls 102. The sides of the spring clip ring 104 slide within opposing guides 108. In one embodiment, the guides 108 are, for example grooves, channels, or parallel raised lips formed within or on the surface of opposing sides of each divider wall 102. Each guide 108 begins, for example at an upper most end of the walls 102 and extend downward.

In one embodiment, the spring clip ring 104 includes a rigid framework formed of an outer portion 110 and a lens support portion comprising a plurality of spring-loaded arms 112 that are biased inward relative to the outer portion 110. In this respect, the plurality of arms 112 apply opposing pressure against the edge or edges of the lens 22, thereby securing the lens 22 in a removable arrangement.

In one embodiment, the spring clip ring 104 is formed of a wire and has an internal diameter of about 82 millimeters and an external diameter of about 85 millimeters. The walls 102 have a height of, for example, about 85 millimeters and are spaced, for example, about 90 millimeters from each other. The guides 102 have a height of, for example, about 65 millimeters, a width of about 7 millimeters and a depth of about 7 millimeters.

The spring clip ring 104 is sized such that its diameter is larger than the distance between the inner surfaces of two adjacent divider walls 102, but smaller or nearly the same size as the distance between the interior surface of the opposing guides 108. Hence, the spring clip ring 104 can be simultaneously slid into each guide 108, starting at the upper, open ends of the guides 108 and rests upon the lower, closed end of the guide 108.

In one embodiment, each guide 108 is preferably located between the top of each divider wall 102 and a position about halfway down the vertical height of the wall 102. In another embodiment, the guide 108 is located between the top of each divider wall 102 and any lower point that would maintain the spring clip ring 104 between the top and bottom of the divider walls 102. In yet another embodiment, the guide 108 extends the entire length of the divider wall 102, allowing the spring clip ring 104 to rest on a lower horizontal surface of the drum 100.

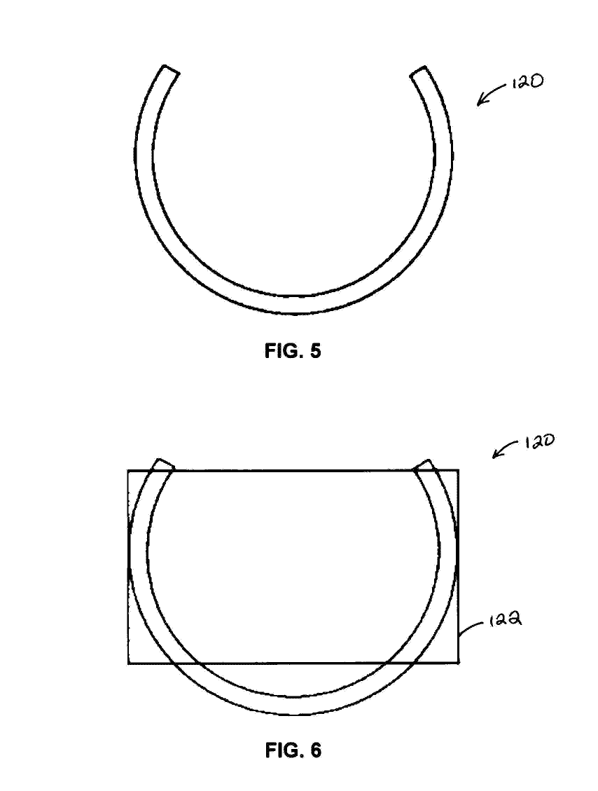

With reference to FIGS. 5-9, in another embodiment of the present invention, instead of employing spring clip ring 104 to attach the lens 22 to the drum 100, a curved fixture 120 is employed to secure the lens 22 to the drum 100. The fixture 120 is formed of an elongated rigid member having a generally ring, crescent, “C-shape,” or broken or incomplete-circle shape. The gap between ends of the fixture 120 is, for example, between 180 degrees and 0 degrees (i.e., a full circle). Alternatively, the fixture 120 is formed of a non-circular or a crescent shape, for example, in the shape of a square, rectangle or octagon. In certain embodiments, the fixture 120 is, for example, formed from a metallic wire having a diameter of about 78 millimeters and forms a ring shape having an overall diameter of about 85 millimeters.

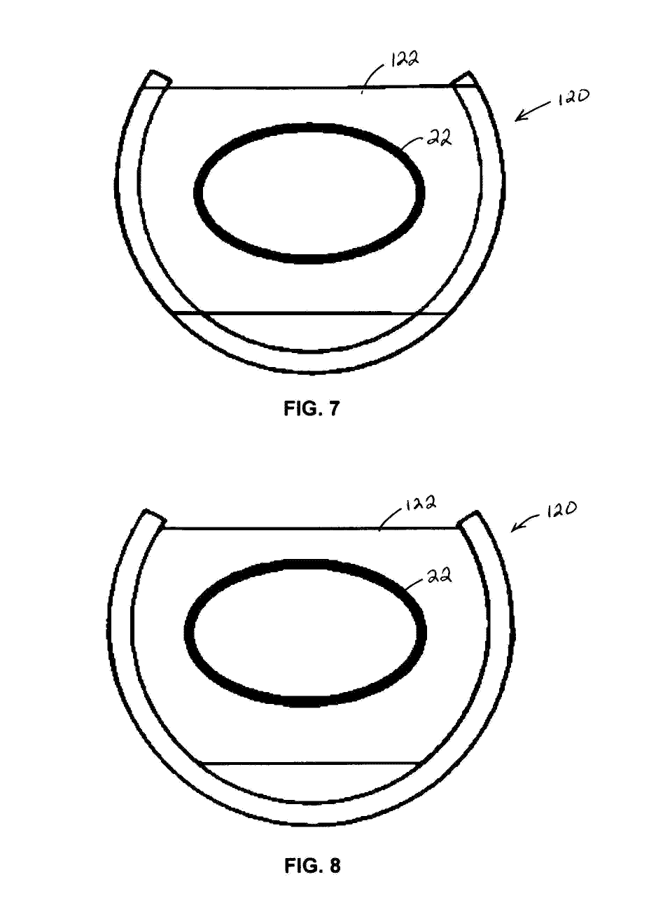

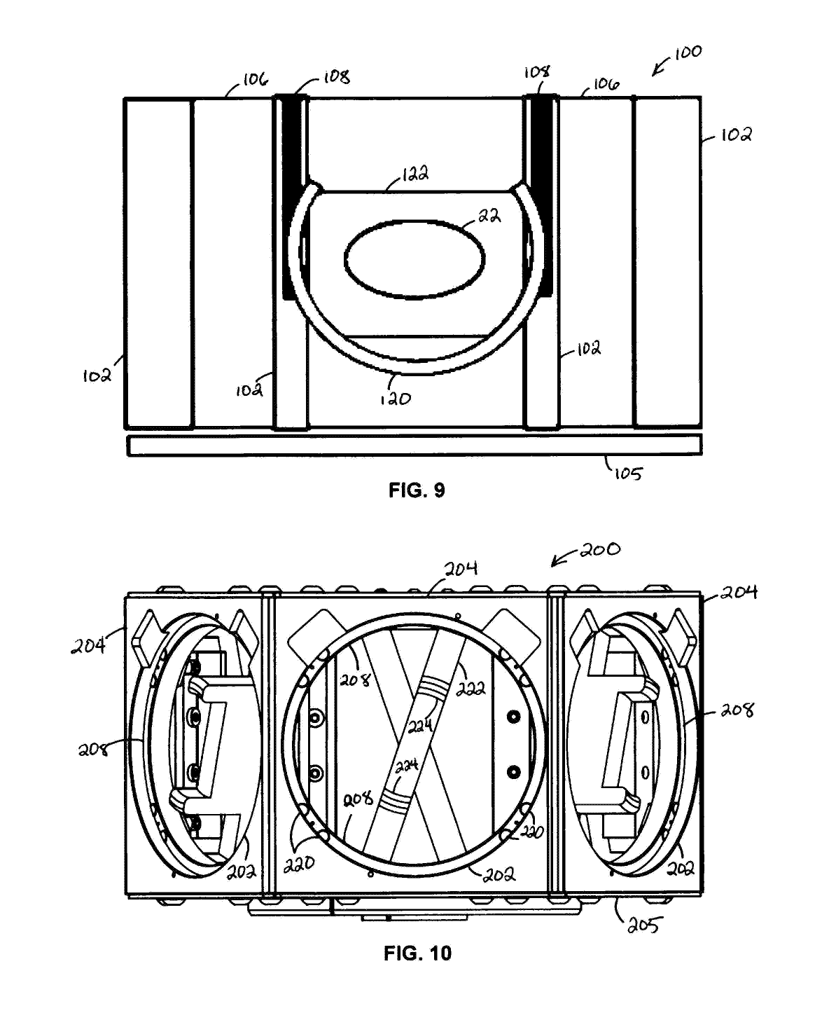

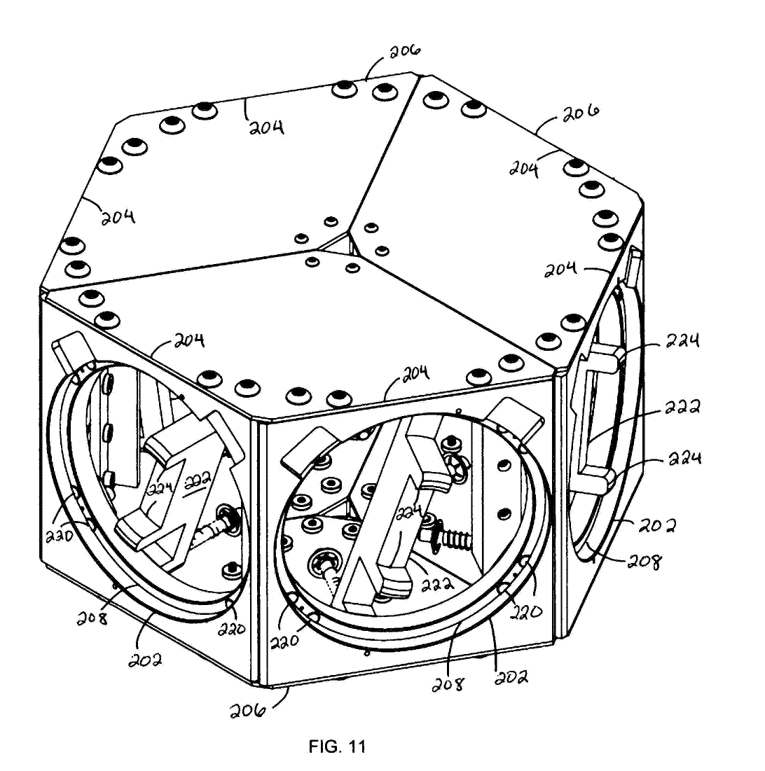

With reference to FIG. 6, in operation, a portion of a tape 122 having a single adhesive side for example, “surface saver” tape which is known in the ophthalmic lens industry, is adhered to one side of the fixture 120. Any excess portions of the tape 122 extending beyond the sides of the fixture 120 are either trimmed or wrapped around the fixture 120. As shown in FIGS. 7 and 8, the ophthalmic lens 22 is positioned against the adhesive side of the tape 122 such that one side is adequately covered by the tape 122 to prevent deposition coating onto the covered side of the lens 22.

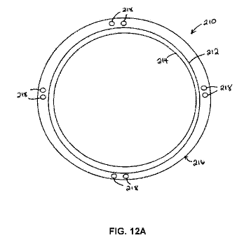

As shown in FIG. 9, the fixture 120 is then slid into the channel guides 108 of two divider walls 102, leaving one side of the lens 22 completely covered with tape 122 and the other side of the lens 22 completely exposed for vapor deposition of a coating, such as an anti-reflective coating.

It should be understood that other connection and support mechanisms are contemplated for use in addition to or in alternative of guides 108. For example, the spring clip ring 104 and the fixture 120 may employ hooks that engage openings or loops formed in or on the drum divider walls 4. Additionally, it should be understood that the spring clip ring 104 and the fixture 120 may alternately employ attachment mechanisms that connect directly to the drum side 6. For example, one or more hooks can be fixed to the drum side 6, allowing the spring clip ring 104 and the fixture 120 to be supported or suspended by the spring ring outer portion 110 or the fixture 120, respectively.

In yet another embodiment according to the present invention, with reference to FIGS. 10 and 11, a drum 200 has, for example, six drum sides 204. Each drum side 204 having a drum aperture 202 formed therein. In contrast to the previously described drums 10 and 100, the drum 200 does not employ divider walls 4, 102. In certain situations, omission of the divider walls 4, 102 is advantageous because it simplifies fabrication of the drum and ultimately provides for a more robust drum.

Formed within the drum aperture 202 is a drum aperture lip 208 that has a diameter that is slightly reduced from the diameter of the drum aperture 202. Formed on a surface of the aperture lip 208 are drum magnets 220. A difference in a diameter of the drum aperture lip 208 and a diameter of the aperture lip 208 represents a width of the drum aperture lip 208.

The drum 200 is, for example, of a modular design employing a plurality of drum segments 206, for example 3 drum segments 206 combine to from the completely assembled drum 200. The drum segments 206 may be formed of a plastic or metallic material. The drum segments 206 are secured to one another by employing a system of corresponding magnets on the surfaces of the segments 206 that are intended for mating against an adjacent segment 206. This configuration advantageously allows for easier disassembly of the drum 200 for accessing an interior of the drum 200 for cleaning, maintenance, and repair.

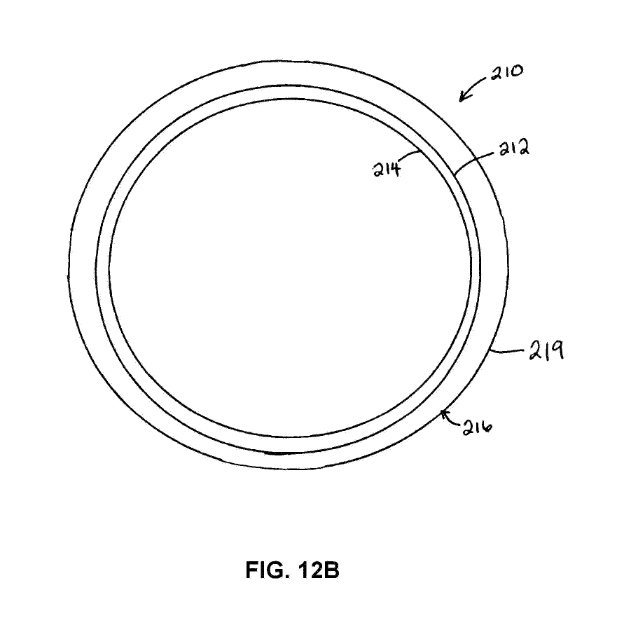

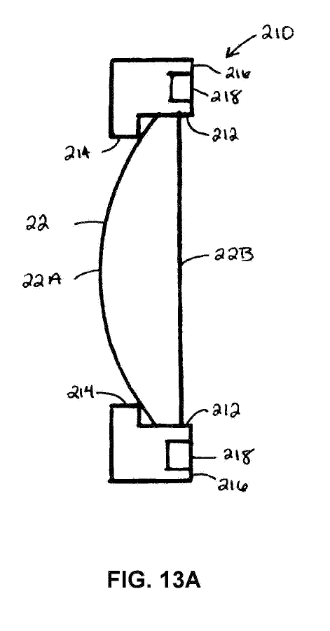

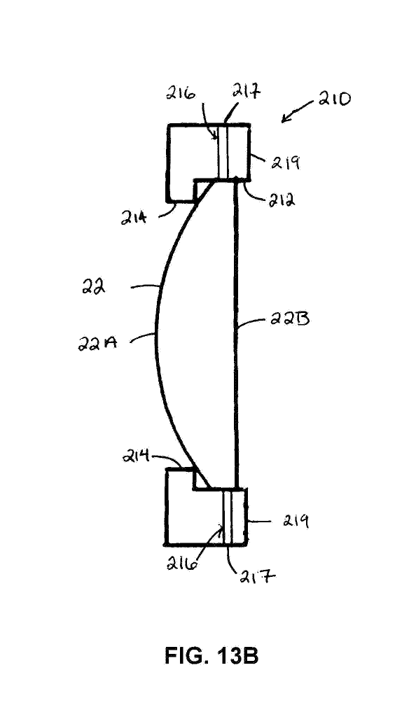

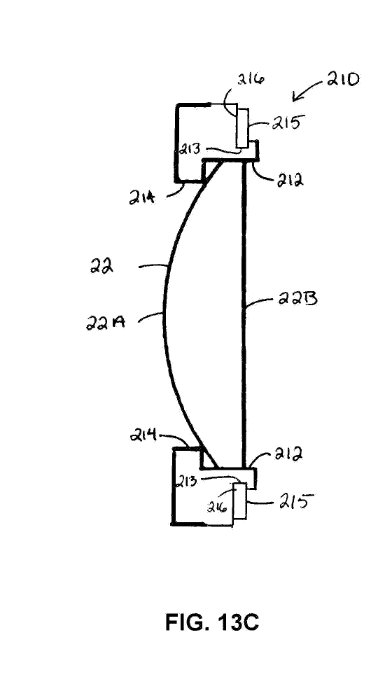

In order to secure the lens 22 to the drum 200 a lens holding assembly 210 is employed. The lens holding assembly 210, shown in FIGS. 12 and 13, has an annular or ring shape forming a lens aperture 212. The assembly 210 may be formed of a plastic or metallic material. The lens aperture 212 is sized to receive a fixed shape lens 22, such as an uncut semi-finished lens. Formed within the lens aperture 212 is a retaining lip 214 that has a diameter that is slightly reduced from a diameter of the lens aperture 212 and a diameter of the lens 22.

A width of the lens holding assembly 210, i.e. a minimum distance from an exterior surface of the annular assembly 210 to the interior surface of the lens aperture 212 may but need not be approximately equal to the width of the drum aperture lip 208.

On a backside 216 of the holder assembly 210 are holder magnets 218. The holder magnets 218 may form a surface or a portion of a surface of the backside 216 of the holder assembly 210. In certain embodiments, as shown in FIGS. 12A and 13A, the holder assembly 210 is formed of a plastic and the magnets 218 may be inserted and secured within holes formed in the surface of the backside 216.

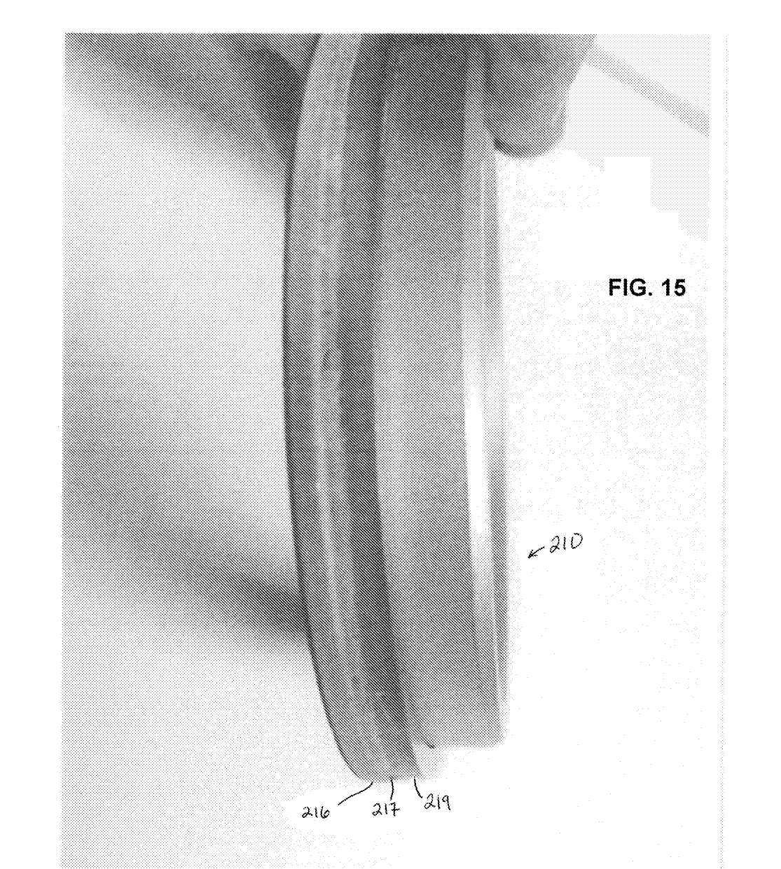

In certain embodiments, the holder assembly 210 is formed of a metallic material and the metallic material may function as a retaining magnet or interact with the magnets 220 shown in FIG. 11 to securely retain the holder assembly 210. In one embodiment of the present invention, as shown in FIGS. 12B and 13B, a ring magnet or magnetic material 219 may be employed on the backside 216 of the holder assembly 210. As shown in FIGS. 13B and 15, the ring magnet or magnetic material 219 may be secured or attached to the backside 216 of the holder assembly 210 by an adhesive 217.

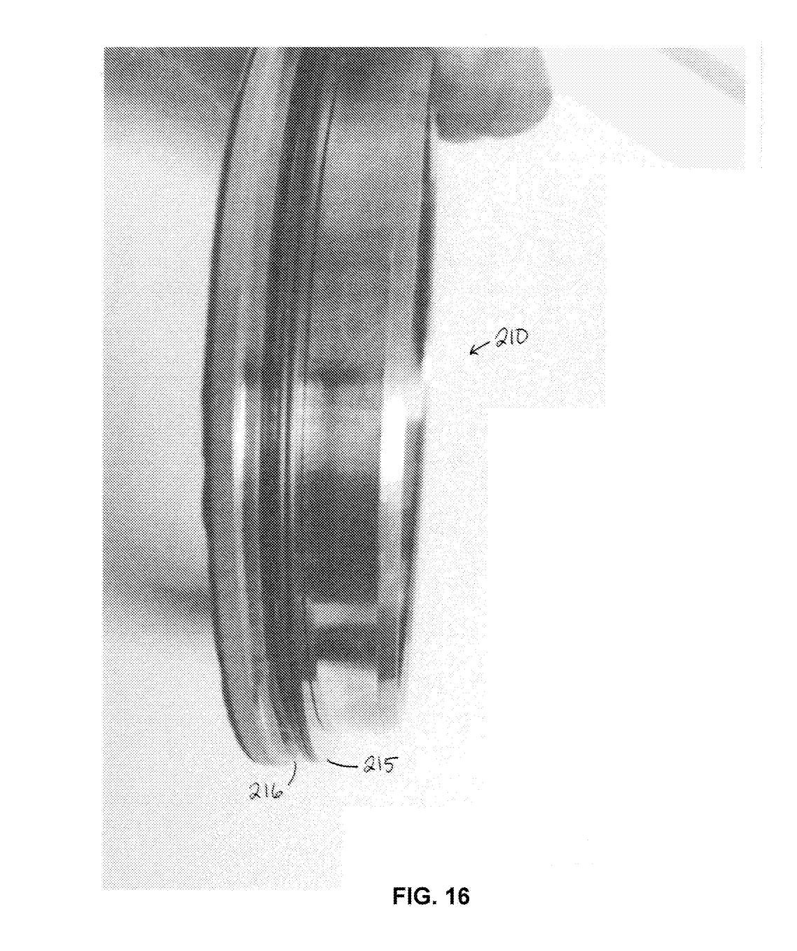

Alternatively, in one embodiment of the present invention, as shown in FIGS. 13C and 16, a snap-ring 215 made of a magnetic material such as steel is employed on, approximate to, or near the backside 216 of the holder assembly 210. In operation, the magnetic snap-ring 215 is fixed in place in a machined or molded groove 213 formed in the lens holder assembly 210. This permits the lens holder assembly to be manufactured from a variety of materials including, for example, aluminum and/or plastic. This embodiment may be advantageous because the absence of the adhesive 217 reduces outgassing in vacuum and prevents eventual failure of the part due to degradation of the adhesive.

With reference to FIGS. 13A-C, in operation, the lens 22 is slid into the lens aperture 212 from the backside 216 of the holder assembly 210 until the surface 22A of the lens 22 to be coated abuts the retaining lip 214. Once in position, the lens 22 will occupy an approximate entirety of the area of the aperture 212. The holder assembly 210 loaded with a lens 22 is then inserted into the drum aperture 202. The holder assembly 210 is secured or held within the drum aperture 202 by the attraction of the magnets 218, retaining magnet 219, magnetic snap-ring 215, or by the magnetism inherent in a metallic material of the holder assembly 212 and the drum magnets 220. It is also noted that by using this holder assembly 210, the backside 22B of the lens 22 is protected from any overspray of the coating deposition, as described above.

In order to prevent the lens 22 from falling towards and/or out from the backside 216 of the aperture 212 and into the interior of the drum 200, a backstop 222 is employed at each of the drum apertures 202 of the drum 200. With reference to FIGS. 10 and 11, the backstop 222 is secured within the interior of the drum 200 so as to be reversibly biased or spring loaded in an outwardly direction through a corresponding drum aperture 202. One or more portions 224 of the backstop 222 may project outward from the interior of the drum 200 to and/or through a plane defined by the circumference of the drum aperture 202.

In operation, as the holder assembly 210 loaded with the lens 22 is inserted into the drum aperture 202, the one or more portions 224 of the backstop 222 will contact a surface 22B of the lens 22 and prevent the lens 22 from falling from the backside 216 of the aperture 212 and into the interior of the drum 200. However, as the attraction of the magnets 218 of the holder assembly 212 and the drum magnets 220 pull and secure the holder assembly 210 within the drum aperture 202, the spring loaded backstop 222 deflects in a direction towards an interior of the drum 200. Alternatively stated, the attractive force of the magnets 218 of the holder assembly 212 and the drum magnets 220 is greater than the counter force applied to the surface 22B of lens 22 by the backstop 222.

In certain embodiments of the present invention, the backstop 22 is in the form of a linear beam positioned and secured within the drum 200 so as to span across a portion of the corresponding drum aperture 202, as shown in FIGS. 10 and 11. The one or more portions 224 of the backstop 222 may be in the form of two projections that extend outward from the backstop 222 positioned within the interior of the drum 200 to and/or through a plane defined by the drum aperture 202. It should be understood that other forms of the backstop 222 and portions 224 may also be employed depending, in part, on the shape and size of the lens 22 being coated.

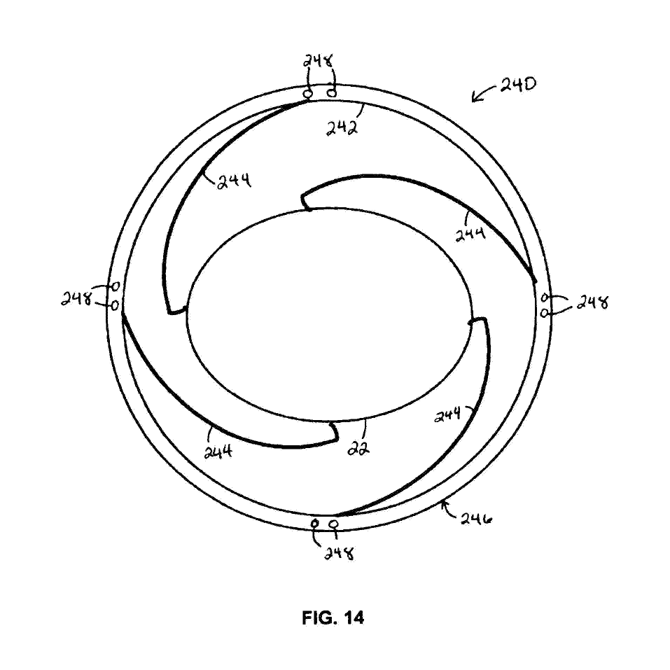

In another embodiment of the present invention, in order to secure the lens 22 to the drum 200 a lens holding spring assembly 240 is employed. The lens holding spring assembly 240, shown in FIG. 14, has an annular or ring shape with a lens aperture 242 formed therein. The assembly 240 may be formed of a plastic or metallic material. Within the lens aperture 242 are a plurality of spring arms 244 that are biased inward to an interior of the lens aperture 242. The lens holding assembly 240 is advantageous for the securing and coating of lenses of varying or non-standard shapes and sizes, for example, cut ophthalmic lenses. In this respect, the plurality of arms 244 apply opposing pressure against the edge of the lens 22, thereby securing the lens 22 within the assembly 240 in a removable arrangement.

A width of the lens holding assembly 240, i.e. a minimum distance from an exterior surface of the annular assembly 240 to the interior surface of the lens aperture 242, may but need not be approximately equal to the width of the drum aperture lip 208 previously described.

On a backside 246 of the holder assembly 240 are assembly holder magnets 248. The assembly holder magnets 248 may form a surface or a portion of a surface of a backside 246 of the holder assembly 240. In embodiments in which the holder assembly 240 is formed of a plastic, the magnets 248 may be inserted and secured within holes formed in the surface of the backside 246. In embodiments in which the holder assembly 240 is formed of a metallic material, the metallic material may function as the magnet 248.

In operation, the lens 22 is inserted between the spring arms 244. The holder assembly 240 loaded with a lens 22 is then inserted into the drum aperture 202. The holder assembly 240 is secured or held within the drum aperture 202 by the attraction of the magnets 248 of the holder assembly 240 and the drum magnets 220.

In order to prevent the backside 22B of lens 22 from accidental coating by coating material entering the interior of the drum 200 through the annular space between the lens 22 and the interior surface of the lens aperture 242, an assembly backing may be employed. The assembly backing may be in the form of a rigid or semi-rigid material, for example a plastic or metallic sheet or foam board, that is positioned between the lens 22 being held within the assembly 240 and the backstop 222 of the drum 200. Alternatively, the backing may be in the form of plastic wrap or a single sided adhesive, for example “surface saver” that is wrapped over the backside 246 of the lens holder assembly 240 prior to insertion of the assembly into the drum aperture 202.

While the above-described drums 100 and 200 have been shown in the figures as employing sides and drum apertures that present the surface 22A of the loaded lens 22 to a coating system or devise in a substantially perpendicular orientation relative to drum bottom 105 and 205, respectively, in certain embodiments of the present invention, it may be desirable to employ a drum 100 or 200 that orients the surface 22A of the loaded lens 22 in an orientation relative to drum bottom 105 and 205 that is substantially non-perpendicular. Such circumstances may arise, for example, when it is desirable to apply a coating on the surface 22A of the loaded lens 22 that varies from one side the surface 22A to the other.

In certain embodiments of the present invention, a substantially non-perpendicular orientation of the surface 22A of the loaded lens 22 is achieved by varying the angle of the sides 106 of the drum 100 or the sides 204 of the drum 200. In such embodiments, the non-perpendicular orientation of the sides 102 of the drum 100 or the sides 204 of the drum 200 may be either static or adjustable.

In certain embodiments of the present invention, a substantially non-perpendicular orientation of the surface 22A of the loaded lens 22 is achieved by varying the angle of the drum aperture 202 relative to the sides 204 of the drum 200. In certain other embodiments of the present invention, a substantially non-perpendicular orientation of the surface 22A of the loaded lens 22 is achieved by varying the angle of the lens aperture 212 of the lens holding assembly 210 relative to the sides 204 of the drum 200.

Although the invention has been described in terms of particular embodiments and applications, one of ordinary skill in the art, in light of this teaching, can generate additional embodiments and modifications without departing from the spirit of or exceeding the scope of the claimed invention. Accordingly, it is to be understood that the drawings and descriptions herein are proffered by way of example to facilitate comprehension of the invention and should not be construed to limit the scope thereof.

What is claimed is:

1. A system for coating optical lenses comprising:
a housing having at least two sides through which an aperture is formed; and
a lens holder having a lens aperture that accepts an optical lens, an exterior shape and size that is complementary and is accepted within the aperture of the housing, and a magnetic back surface.

2. The system of claim 1 wherein the housing has six sides.

3. The system of claim 1 wherein the lens aperture comprises a plurality of spring arms.

4. The system of claim 1 wherein the lens aperture is sized and shaped to accept an uncut optical lens blank.

5. The system of claim 1 wherein the housing comprises a magnet that collaborates with the magnetic back surface of the lens holder to hold the lens holder within the aperture of the housing.

6. The system of claim 1 wherein the housing comprises a spring loaded back stop that prevents a movement of the optical lens from the lens aperture of the lens holder.

7. The system of claim 1 wherein the lens aperture of the lens holder comprises a lens retaining lip.

8. The system of claim 1 further comprising a backing positioned between a backside of the optical lens and an interior of the housing.

9. The system of claim 1 wherein the magnetic back surface of the lens holder comprises a snap ring.

10. The system of claim 1 wherein the at least two sides of the housing are oriented approximately perpendicular to a base of the housing.

11. A system for coating optical lenses comprising:
a housing having a plurality of sides with first apertures; and
an annular lens holder accepted within one of the first apertures, the lens holder having a second aperture that accepts an optical lens; and
a securing element that maintains the lens holder within the first aperture, the securing element incorporating a magnet associated with each of the first apertures and a magnetic back surface of the lens holder.

12. The system of claim 11 wherein the second aperture comprises a plurality of spring arms.

13. The system of claim 11 wherein the magnetic back surface of the lens holder is a snap ring.

14. The system of claim 11 wherein the housing comprises a plurality of housing segments, each housing segment forming at least two of said sides with first apertures.

15. A method for holding an optical lens during coating comprising:
inserting an optical lens within a lens holding assembly;
securing the lens holding assembly within an aperture of a housing by forming a magnetic attraction between a substantially entire back surface of the lens holder and a magnet of the housing;
preventing a backside of the optical lens from being coated;
loading the housing into a coating device; and
coating at least a portion of the optical lens while rotating the housing within the coating device.

16. The method of claim 15 wherein the step of inserting an optical lens within a lens holding assembly comprises inserting an optical lens between a plurality of spring arms.

17. The method of claim 15 wherein the step of inserting an optical lens within a lens holding assembly comprises inserting an optical lens having a shape that corresponds approximately to the size and shape of the second aperture.

18. The method of claim 15 wherein the step of securing the lens holding assembly within an aperture of a housing by forming a magnetic attraction between a substantially entire back surface of the lens holder and a magnet of the housing comprises employing a magnetic snap ring.

19. The method of claim 15 wherein the step of preventing a backside of the optical lens from being coated comprises employing a back stop between a backside of the optical lens and an interior of the housing.

20. The method of claim 15 wherein the step of coating at least a portion of the optical lens while rotating the housing within the coating device comprises uniformly coating a majority of a from surface of the optical lens.
